(19) United States
(12) Patent Application Publication
(10) Pub. No.: US 2026/0235133 A1
(43) Pub. Date: Aug. 13, 2026

(54) FAN REGULATING SYSTEM AND FAN SPEED REGULATING METHOD

(71) Applicant: Wistron Corporation, New Taipei City (TW)

(72) Inventors: Guo Shu HUANG, New Taipei City (TW); Yijiun LIN, New Taipei City (TW)

(21) Appl. No.: 19/216,810

(22) Filed: May 23, 2025

(30) Foreign Application Priority Data
Feb. 13, 2025 (TW) 114105430

(51) Int. Cl. F04D 27/00; H05K 7/20

(52) U.S. Cl. CPC F04D 27/004; F04D 27/001; H05K 7/20727; H05K 7/20836

(57) ABSTRACT

A fan regulating system and a fan speed regulating method are provided. The fan regulating system comprises a chassis, a fan, a pressure sensor, and a controller. The chassis includes a housing and a cover. The housing has an opening. The cover is configured to cover the opening. The fan is arranged inside the housing, and the fan has a vent. The pressure sensor is arranged inside the housing and adjacent to the vent. The pressure sensor is configured to measure a pressure value in the chassis. The controller is coupled to the pressure sensor and the fan. The controller is configured to calculate a plurality of determining conditions according to the pressure value and to regulate a speed value of the fan according to the plurality of determining conditions.

### CROSS-REFERENCE TO RELATED APPLICATION

This non-provisional application claims priority under 35 U.S.C. § 119(a) to patent application No. 114105430 filed in Taiwan, R.O.C. on Feb. 13, 2025, the entire contents of which are hereby incorporated by reference.

### BACKGROUND

### Technical Field

The present disclosure relates to a fan regulating system and a control method, and in particular, to a fan regulating system including a fan and a fan speed regulating method.

### Related Art

With continuous improvement of server performance, heat dissipation management is always a critical issue in design. To ensure that servers operate within a safe temperature range, various protection mechanisms are widely adopted. Generally, the fans and cooling systems within a server chassis are configured based on the arrangement layout of components in an enclosed space. However, if a server cover is not properly closed, the airflow generated by the fans may escape through a server's opening, preventing the internal components from being adequately cooled. This can lead to an overheating issue, which not only affects system stability but also the lifespan of components.

One solution known to the applicant is to detect a cover status by using a physical sensor. For example, an intrusion cable is used as a trigger switch for monitoring the cover status. When the cover comes into contact with a mechanical structure (such as a roller, a lever, or a button) of the sensor, the mechanical structure is subjected to a press or a pull to trigger switching of the control circuit, thereby generating a sensing signal. However, the complexity of sensor installation, space requirements, and cost are important considerations. For example, the installation configuration of the mechanism increases the complexity of internal cabling and requires more mechanical space. This may further affect a configuration layout of other components.

### SUMMARY

In view of this, one embodiment of the present disclosure provides a fan regulating system, comprising a chassis, a fan, a pressure sensor, and a controller. The chassis includes a housing and a cover. The housing has an opening. The cover is configured to cover the opening. The fan is arranged inside the housing, and the fan has a vent. The pressure sensor is arranged inside the housing and adjacent to the vent. The pressure sensor is configured to measure a pressure value inside the chassis. The controller is coupled to the pressure sensor and the fan. The controller is configured to calculate a plurality of determining conditions according to the pressure value and to regulate a speed value of the fan according to the plurality of determining conditions.

Another embodiment of the present disclosure provides a fan speed regulating method, for regulating a fan. The fan speed regulating method comprises: reading a pressure value; calculating an instantaneous pressure value according to the pressure value; in response to the instantaneous pressure value being greater than a pressure threshold, obtaining a pressure variation value of the pressure value before and after a preset period; in response to the pressure variation value being less than a lower limit of a pressure difference range, determining whether the pressure variation value is in a second slope range; and in response to the pressure variation value being in the second slope range, increasing the speed value.

### BRIEF DESCRIPTION OF THE DRAWINGS

FIG. 1A is a schematic diagram of component layout of a fan regulating system according to some embodiments.

FIG. 1B is a schematic block diagram of a fan regulating system according to some embodiments.

FIG. 2 is a perspective view of component layout of a fan regulating system according to some embodiments.

FIG. 3 is a schematic diagram of a pressure sensing signal according to some embodiments.

FIG. 4 is a flowchart of a fan speed regulating method according to some embodiments.

FIG. 5A to FIG. 5C are schematic diagrams of pressure sensing signal variations according to different embodiments.

FIG. 6 to FIG. 8 are schematic diagrams of pressure sensing signal variations under different fan speed statuses according to different embodiments.

FIG. 9A and FIG. 9B are schematic diagrams of a slope range of pressure sensing signal variations according to different embodiments.

### DETAILED DESCRIPTION

The term “one” or “a” in this specification are used to describe elements and components of the present disclosure. The term is merely used for convenience of description and to give a basic concept of the creation. This description should be understood as including one or at least one, and unless obviously meant otherwise, the singular also includes the plural.

Unless otherwise specified, space descriptions such as “above”, “below”, “left”, “right”, “front”, “rear”, “inside”, and “outside” are indicated with respect to directions shown in the figures. It should be understood that the space descriptions used in this specification are merely for the purpose of description, and actual implementations of the structures described in this specification may be configured in space in any relative direction. This limitation does not change advantages of embodiments of the present disclosure.

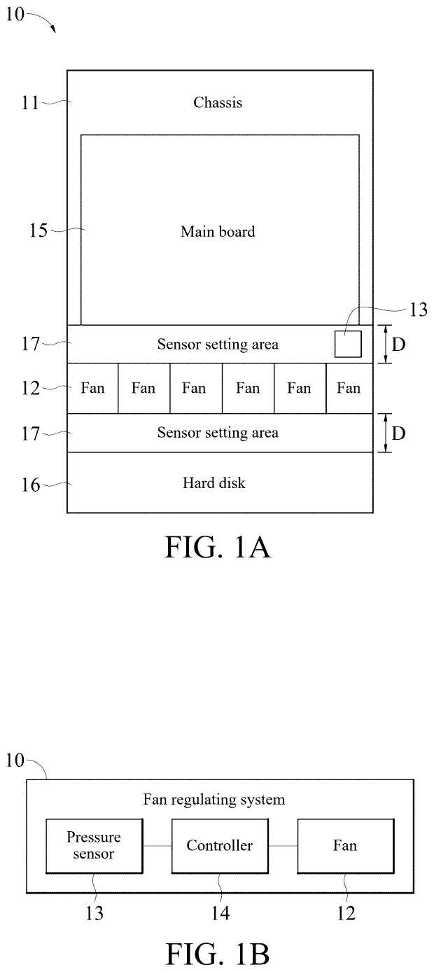

FIG. 1A is a schematic diagram of component layout of a fan regulating system according to some embodiments. FIG. 1B is a schematic block diagram of the fan regulating system according to some embodiments. Referring to FIG. 1A and FIG. 1B together, in the embodiments, a fan regulating system 10 includes a chassis 11, a fan 12, a pressure sensor 13, a controller 14, a main board 15, and a hard disk 16. The fan 12, the pressure sensor 13, the main board 15, and the hard disk 16 are arranged inside the chassis 11. The fan 12 and the pressure sensor 13 are respectively electrically connected to the controller 14. A sensor setting area 17 is arranged adjacent to the fan 12. A range of the sensor setting area 17 is suitable for configuring the pressure sensor 13. In the embodiments, the pressure sensor 13 is configured at the front right of a plurality of fans 12 (the top right in FIG. 1A). The sensor setting area 17 is not required to be a range clearly marked on a structure, for example, a range defined by using a line mark or a mechanism interface line, but may refer to an adjacent range of the fan 12.

Specifically, a setting area width D of the sensor setting area 17 is configured according to a design requirement. In the embodiments, the chassis 11 has a housing length L of 700 mm, and the setting area width D is 100 mm. Therefore, sensor setting areas 17 in front of or at the rear of the plurality of fans 12 respectively occupy approximately 1/7 of the housing length L. In some embodiments, the adjacent range may alternatively be configured according to a relative relationship between components. For example, a range between the fan 12 and a heating component is defined as an adjacent position of the fan 12. The heating component may be a single component or an integrated component whose temperature may be increased to be higher than a room temperature in a working state. In the embodiments, the heating component is the hard disk 16 and the main board 15. Therefore, one sensor setting area 17 is configured between the fan 12 and the main board 15, and the other sensor setting area 17 is configured between the fan 12 and the hard disk 16. In some embodiments, a range of the sensor setting area 17 overlaps a range of the main board 15. In other words, the pressure sensor 13 may be arranged on the main board 15.

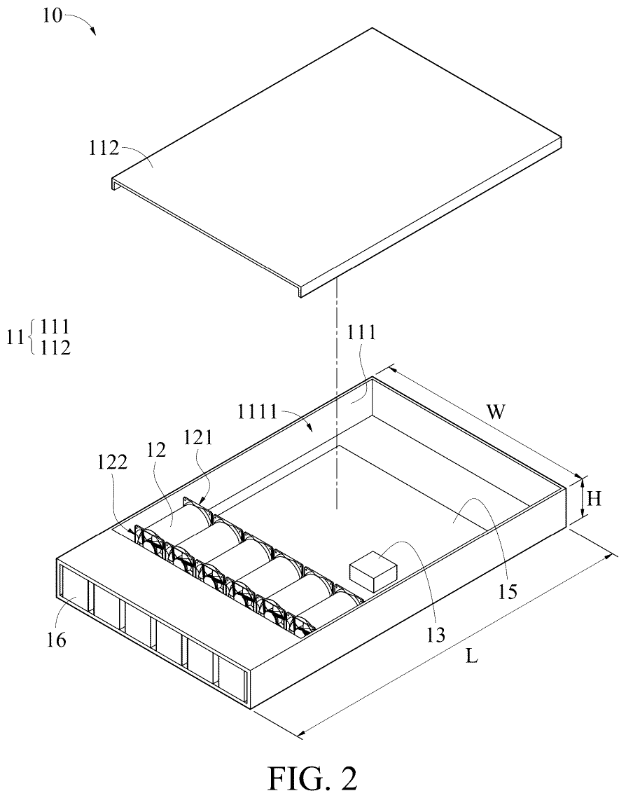

FIG. 2 is a perspective view of component layout of a fan regulating system according to some embodiments. Referring to FIG. 1A, FIG. 1B, and FIG. 2 together, the chassis 11 includes a housing 111 and a cover 112. The housing 111 has an opening 1111. The cover 112 is configured to cover the opening 1111. In the embodiments, the opening 1111 of the housing 111 is located at an upper portion and the cover 112 is an upper cover. However, the present disclosure is not limited thereto. For example, the cover 112 may alternatively be a front cover or a rear cover of the chassis 11. The housing 111 of the chassis 11 has the housing length L, a housing width W, and a housing height H. The fan 12, the pressure sensor 13, the main board 15, and the hard disk 16 are arranged inside the housing 111. The pressure sensor 13 is arranged on the main board 15 and adjacent to the fan 12. The housing 111 of the chassis 11 is in a semi-open state. When the cover 112 is placed over the opening 1111, the chassis 11 is in an enclosed state. The enclosed is not limited to complete sealing. For example, the housing 111 or the cover 112 may be provided with a plurality of heat dissipation holes (not shown). A size of the heat dissipation holes is smaller than that of the opening 1111. In some embodiments, a diameter of a single heat dissipation hole is smaller than a maximum size of the fan 12.

The fan 12 has a vent. The vent is not limited to an air inlet or an air outlet. As shown in FIG. 2, the fan 12 has a vent 121 and a vent 122. The vent 121 is an air outlet and the vent 122 is an air inlet. Air inside the housing 111 is driven out of the chassis 11 through the vent 122 of the fan 12, the vent 121 of the fan 12, and the heat dissipation holes of the housing 111. An air flow can cause a pressure variation inside the housing 111. A speed of the fan 12 may be regulated by using a direct current control signal or a pulse-width modulation (PWM) control signal. A speed value of the fan 12 is positively correlated with a direct current voltage, a current, or a duty cycle of the control signal. The pressure sensor 13 is configured to measure a pressure value inside the housing 111. The pressure value is not limited to a physical quantity derived from air pressure or sound pressure, for example, an air pressure variation caused by an air flow, or a sound pressure variation caused by a disturbed flow of the fan 12. The pressure sensor 13 converts the pressure value into a sensing signal of a voltage or a current. The pressure sensor 13 may be a piezoelectric sensor or a capacitive pressure sensor, for example, a speaker or a MEMS microphone. As described above, the pressure sensor 13 is arranged in the sensor setting area 17 and adjacent to the fan 12. As shown in FIG. 2, in the embodiments, the pressure sensor 13 is arranged in an adjacent range of the vent 121 (e.g., the air outlet) of the fan 12. In other embodiments, the pressure sensor 13 is arranged in an adjacent range of the vent 122 (e.g., the air inlet) of the fan 12. In addition, a plurality of pressure sensors 13 may alternatively be provided, and the plurality of pressure sensors 13 are arranged in the adjacent ranges of the vent 121 and the vent 122.

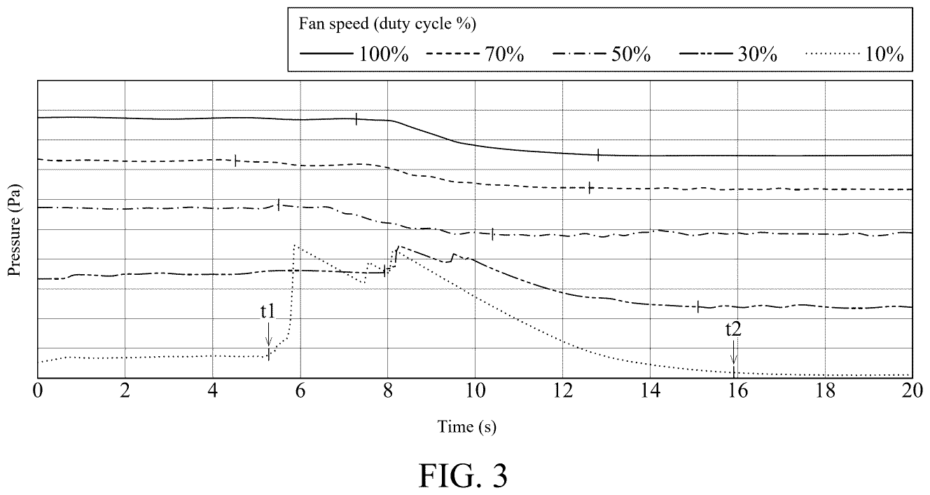

FIG. 3 is a schematic diagram of a pressure sensing signal according to some embodiments. Referring to FIG. 3, a horizontal axis in FIG. 3 indicates time(s), and a vertical axis indicates a pressure (Pa). Curves represent pressure values measured by the pressure sensor 13 at different speeds of the fan 12. The speed of the fan 12 is defined according to a control signal thereof. The control signal is a PWM control signal, and separately corresponds to duty cycles of 100%, 70%, 50%, 30%, and 10%. Values of the curves are pressure values obtained through conversion according to a sensitivity and an output voltage (current) of the pressure sensor 13. To be specific, output voltage (current)=sensitivity*pressure. Using a speed of the fan 12 corresponding to the duty cycle of 10% as an example, a time point t1 indicates that a state switching event of the cover 112 occurs, and a time point t2 indicates that the state switching event of the cover 112 ends. The state switching event may be an event in which the opening 1111 of the housing 111 is converted from an open state into a state in which the opening 1111 is covered by the cover 112, or an event in which the opening 1111 of the housing 111 is converted from the state in which the opening 1111 is covered by the cover 112 into the open state. In the embodiments, as shown in FIG. 3, the sensing signal indicates that the pressure value at the time point t2 is less than the pressure value at the time point t1. This indicates that the cover 112 is removed at the time point t1, in other words, the opening 1111 of the housing 111 is converted from the state in which the opening 1111 is covered by the cover 112 into the open state, so that the pressure value inside the housing 111 is reduced. Therefore, the sensing signal generated by the pressure sensor 13 may reflect whether the cover 112 is moved, and whether the cover 112 is placed over or is detached from the housing 111. Details are described below.

Referring to FIG. 1A and FIG. 1B again, the controller 14 can receive the sensing signal of the pressure sensor 13, and generate a control signal to regulate the speed of the fan 12. The fan speed regulating method according to one or more of the embodiments of the present disclosure may be programmed as a speed regulating program, and the controller 14 may be configured to execute the speed regulating program, to regulate the speed value of the fan 12 according to the pressure value obtained by the sensing signal. The controller 14 may be a system on a chip (SoC), a central processing unit (CPU), a micro-controller unit (MCU), an application specific integrated circuit (ASIC), a field programmable gate array (FPGA), or a logic circuit. The controller 14 may be arranged in an independent control board or in the main board 15. In some embodiments, the controller 14 is the central processing unit, and the central processing unit executes basic input/output system (BIOS) program code or operating system program code to implement all or some steps of the fan speed regulating method. Alternatively, the controller 14 is a baseboard management controller (BMC), and the BMC executes program code to implement all or some steps of the fan speed regulating method. In some other embodiments, the controller 14 may be a plurality of independent chips, and the chips work together to implement the fan speed regulating method.

In some embodiments, the fan regulating system 10 may include a memory (not shown). The memory may be configured to store program code, parameters, operation data, and a database of the speed regulating program. The controller 14 may read or write the memory to perform the fan speed regulating method. The memory may be a flash memory or a read-only memory (ROM), for example, an erasable programmable read-only memory (EPROM), a flash read-only memory (Flash ROM), or a field-replaceable unit (FRU). In some embodiments, the memory may alternatively be configured to continuously record the pressure value, to allow a person to perform a post-hoc analysis on a pressure status of the fan regulating system 10.

The main board 15 is an integrated component including a plurality of electronic parts. For example, the main board 15 includes a central processing unit or a baseboard management controller. The controller 14 may be arranged on the main board 15, and may be the central processing unit, the baseboard management controller, or an independent chip. The pressure sensor 13 may be arranged in the main board 15, and is electrically connected to the controller 14 through the trace routing of the main board 15; or the pressure sensor 13 may be plugged to a connection port on the main board 15 through a transmission cable, and is electrically connected to the controller 14 through the trace routing of the main board 15. In the embodiments, the fan 12 is electrically connected to the main board 15. The pressure sensor 13 is coupled to the main board 15 and is arranged between the vent 121 of the fan 12 and the main board 15. The main board 15 may be a heat dissipation target of the fan 12. The vent 121 of the fan 12 faces the main board 15. The hard disk 16 is a storage device of the fan regulating system 10, and is electrically connected to the main board 15. The hard disk 16 may be a heat dissipation target of the fan 12. The vent 122 of the fan 12 faces the hard disk 16.

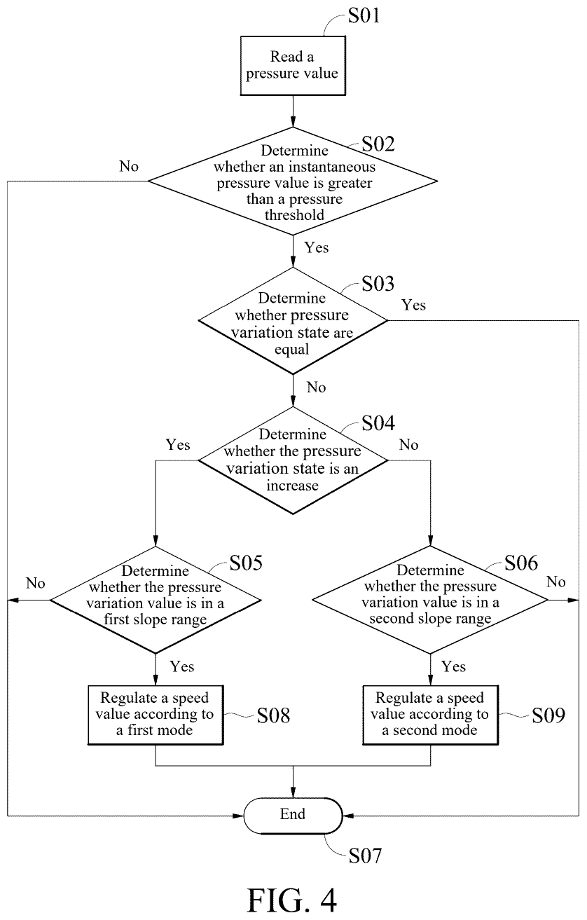

FIG. 4 is a flowchart of a fan speed regulating method according to some embodiments. Referring to FIG. 4, the following embodiment is described by using an example in which a controller 14 executes a speed regulating program of the fan speed regulating method. The controller 14 reads a pressure value from a pressure sensor 13 (step S01), and calculates a time differential of the pressure value to obtain an instantaneous pressure value. The instantaneous pressure value reflects an instantaneous variation of the pressure value. Using a time point t1 in FIG. 3 as an example, a state switching event causes the instantaneous variation of the pressure value. The state switching event reflects an air flow disturbance or a collision sound caused when a cover 112 is placed over or is detached from a housing 111. However, shaking or collision of a chassis 11 may also cause an air flow disturbance or a collision sound;

and if a fan 12 is controlled by another system, the speed may also be increased or reduced, to generate a disturbance sound; or when the pressure sensor 13 suffers electromagnetic interference from a surrounding environment, current noise may also be generated, causing the variation of the instantaneous pressure value of the pressure sensing signal. The foregoing factors may also cause the system to misjudge that the state switching event occurs, which needs to be further excluded. Details are described below.

Different curves in FIG. 3 reflect pressure values of the fan 12 at different speeds. A speed value is related to a pressure value in a steady state, and is also related to a pressure value in a transient state. Specifically, referring to the pressure values before the time point t1 and after a time point t2 in FIG. 3, in this case, the pressure values of the system are in the steady state. A larger speed value of the fan 12 indicates a larger steady-state pressure value. In other words, the fan 12 at a high speed generates a relatively strong air flow and disturbance sound, resulting in a relatively high pressure value. Referring to pressure values between the time point t1 and the time point t2 in FIG. 3, in this case, the pressure values of the system are in the transient state. A smaller speed value of the fan 12 indicates a larger pressure value variation in the transient state. In other words, the fan 12 at a low speed generates a relatively weak air flow and low disturbance sound. Therefore, the pressure value of the fan 12 is more easily affected by the state switching event. Therefore, the instantaneous pressure value reflects occurrence of an event in the transient state, that is, whether the state switching event occurs.

The controller 14 determines whether the instantaneous pressure value is greater than a pressure threshold (step S02). The pressure threshold may be defined as an average or minimum pressure relative difference measured by the pressure sensor 13 before and after the cover is opened (or before and after the cover is closed) when the fan regulating system 10 is under a test condition. Under the test condition, the speed of the fan 12 is set to a minimum value, which corresponds to a lower limit of a specification value of operating power of the fan 12; and the cover 112 is slightly opened (for example, a size of a cover-opening distance is slightly larger than a size of a heat dissipation hole). Specifically, referring to FIG. 2 and FIG. 3, the pressure sensor 13 in the embodiments is a MEMS microphone, and has a sensitivity of 7.9433 (mV/Pa). Seven fans 12 are provided, and a size of each of the fans 12 is 40 mm*40 mm*56 mm. Speed values of the fans 12 are sequentially set to 10% (3000 RPM), 30% (9900 RPM), 50% (15700 RPM), 70% (21400 RPM), and 100% (30000 RPM). The cover 112 is partially opened from one side of an opening 1111, and different cover-opening distances are set for measurement. The cover-opening distances between a boundary of the cover 112 and a boundary of the opening 1111 of the housing 111 are sequentially set to 10 mm, 30 mm, 100 mm, 250 mm, and infinity (that is, the cover 112 is removed). The housing 111 has a housing length L of 700 mm, a housing width W of 425 mm, and a housing height H of 40 mm.

Table 1 presents output voltage differences of the pressure sensor under the test condition according to some embodiments, and Table 2 presents pressure differences obtained through conversion on output voltage differences in Table 1. Referring to Table 1 and Table 2 (shown in the end of the detail description). In the embodiments, a larger cover-opening distance indicates a larger output voltage difference (pressure difference) of the pressure sensor 13. In addition, after the cover-opening distance exceeds a particular value, for example, 250 mm to infinity, the output voltage difference (the pressure difference) of the pressure sensor 13 does not significantly vary. FIG. 3 shows that at a lowest speed of the fan 12, impact of a pressure variation caused by the state switching event is the most prominent; and when the speed of the fan 12 is increased, the impact of the pressure variation caused by the state switching event is gradually reduced. In the embodiments, when the speed of the fan 12 is set to the minimum value 10% and the cover-opening distance is set to 10 mm, a minimum relative pressure difference measured by the pressure sensor 13 before and after the cover is opened is measured as 0.03 Pa. In the embodiments, the instantaneous pressure value merely reflects the occurrence of the state switching event, and is irrelevant to whether the cover 112 is placed over the opening 1111 or is detached from the opening 1111. In some embodiments, the controller 14 determines whether an absolute value of the instantaneous pressure value is greater than the pressure threshold, to determine whether the state switching event in which the cover 112 is placed over or is detached from the opening 1111 occurs. In some embodiments, the pressure threshold is set to 0.03 Pa, and the pressure threshold may be a parameter value stored in the memory.

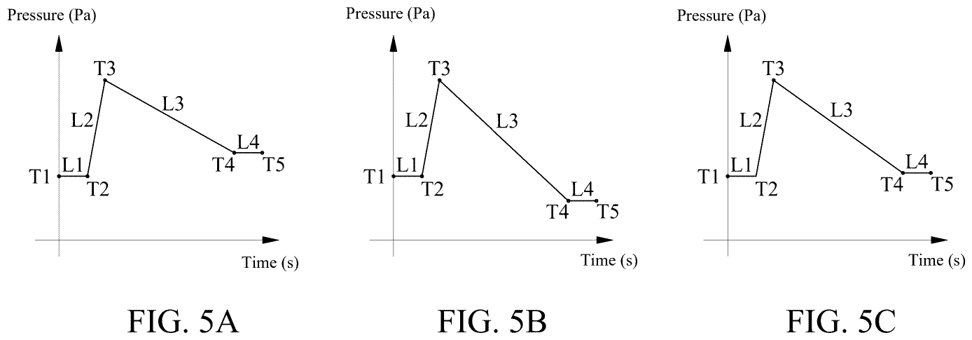

When the controller 14 determines that the instantaneous pressure value is less than the pressure threshold (in step S02, a determining result is “no”), that is, the state switching event does not occur, the controller 14 ends the speed regulating program (step S07). When the controller 14 determines that the instantaneous pressure value is greater than the pressure threshold (in step S02, the determining result is “yes”), the controller 14 further calculates a pressure variation value of the pressure value before and after a preset period. FIG. 5A to FIG. 5C are schematic diagrams of pressure sensing signal variations according to different embodiments. Referring to FIG. 5A to FIG. 5C together, in the embodiments, a time point T1 is a measurement start point, a state switching event may be between a time point T2 and a time point T4, a time point T3 is a pressure peak point, a time point T5 is a measurement end point, and a pressure value is in a steady state during a period L1 and a period L4, and is in a transient state during a period L2 and a period L3. In FIG. 5A, the pressure value during the period L4 is greater than the pressure value during the period L1, which may reflect a state switching event in which the cover is closed. In FIG. 5B, the pressure value during the period L4 is less than the pressure value during the period L1, which may reflect a state switching event in which the cover is opened. In FIG. 5C, the pressure value during the period L4 is equal to the pressure value during the period L1, which may reflect that a state switching event is misjudged. In other words, a pressure variation in the transient state does not actually reflect occurrence of the state switching event. For example, the chassis 11 is shaken to cause an air flow disturbance, the chassis 11 is collided to cause a sound, the fan 12 is externally controlled to increase or reduce the speed, or the pressure sensor 13 suffers electromagnetic interference to generate noise, causing variations of the instantaneous pressure value of the pressure sensing signal.

The preset period may be defined as duration of the transient state measured by the pressure sensor 13 before and after the cover is opened (or before and after the cover is closed), that is, duration of the period L2 and the period L3 when the fan regulating system 10 is under a test condition. Under the test condition, the speed of the fan 12 is set to a minimum value, which corresponds to a lower limit of a specification value of operating power of the fan 12; and the cover 112 is completely opened (that is, the cover 112 is removed). Specifically, referring to FIG. 2 and FIG. 3. FIG. 3 shows that at the lowest speed of the fan 12, it takes longest time for the fan 12 to return to the steady state from the transient state; and when the speed of the fan 12 is increased, time for returning to the steady state from the transient state is gradually shortened. In the embodiments, when the speed of the fan 12 is set to the minimum value 10% and the cover-opening distance is set to infinity, duration of the transient state measured by the pressure sensor 13 before and after the cover is opened (the duration between the time point t1 and the time point t2) is 11 seconds. An intensity variation of the pressure value in the steady state (before the time point t1 and after the time point t2) is from −1 dB to +1 dB. Therefore, the time point t1 is defined as a time point at which an intensity variation of the pressure value is out of the range of −1 dB to +1 dB, that is, a time point at which the steady state is transformed to the transient state. The time point t2 is defined as a time point at which the intensity variation of the pressure value is in the range of −1 dB to +1 dB, that is, a time point at which the transient state is transformed to the steady state. In the embodiments, the preset period reflects the duration of the transient state of the state switching event, to indicate whether the state switching event ends. In some embodiments, the preset period is set to 11 seconds, and the preset period may be a parameter value stored in the memory.

Step S03: The controller 14 determines whether pressure variation states are equal. A pressure variation value reflects a pressure variation state. The pressure variation value may be a variation amount of the pressure value from a first steady state (the period L1) to a second steady state (the period L4). The first steady state and the second steady state are spaced apart by a transient state (the period L2 and the period L3). In some embodiments, when the controller 14 determines that the pressure variation value is in a pressure difference range, the controller 14 determines that the pressure variation states are equal. The pressure difference range may be defined by comparing a pressure value sampling point during the first steady state and a pressure value sampling point during the second steady state and determining that two pressure value sampling points do not significantly differ from each other; or defined according to that an intensity difference between the pressure value during the second steady state and the pressure value during the first steady state is in the range of −1 dB to +1 dB. When the pressure variation states are equal, it indicates that the steady-state pressure inside the chassis 11 does not vary due to an event causing the transient state. Therefore, in step S02, it is determined that the occurrence of state switching event is a misjudgment. In other words, the cover 112 actually is neither placed over nor detach from the opening 1111 of the housing 111.

When the controller 14 determines that the pressure variation states are equal (in step S03, a determining result is “yes”), that is, the first steady state and the second steady state do not change (which corresponds to FIG. 5C), the controller 14 ends the speed regulating program (step S07). When the controller 14 determines that the pressure variation states are not equal (in step S03, the determining result is “no”), the controller 14 further determines whether the pressure variation state is an increase (in step S04, “yes” indicates that the pressure is increased, and “no” indicates that the pressure is reduced). In some embodiments, when the controller 14 determines that the pressure variation value is greater than an upper limit of the pressure difference range, the controller 14 determines that the pressure variation state is an increase, which may indicate that the cover 112 is placed over the housing 111 (which corresponds to FIG. 5A). On the contrary, when the controller 14 determines that the pressure variation value is less than a lower limit of the pressure difference range, the controller 14 determines that the pressure variation state is a decrease, which may indicate that the cover 112 is detached from the housing 111 (which corresponds to FIG. 5B). An impact factor of the pressure variation state is that, an air flow is limited to flow inside the housing 111 after the cover 112 is placed over the opening 1111, causing an increase of an air pressure value in the housing 111; or the air flow escapes from the opening 1111 after the cover 112 is detached from the opening 1111, causing a decrease of the air pressure value in the housing 111. Another impact factor is that, a disturbance sound of the fan 12 is limited to be reverberated inside the housing 111 after the cover 112 is placed over the opening 1111, causing an increase of a sound pressure value in the housing 111; or the disturbance sound of the fan 12 emits from the opening 1111 after the cover 112 is detached from the opening 1111, causing a decrease of the sound pressure value in the housing 111.

Referring to FIG. 5A to FIG. 5C again, Formula 1 may be used for simulating a pressure state during the period L1, the period L2, the period L3, or the period L4:

$$P = \frac{Δ P}{Δ T} T + A \qquad ( Formula 1 )$$

In the formula, P is a pressure value, and ΔP/ΔT is a slope of the pressure value. During the period L1, ΔP may be a pressure difference between the time point T2 and the time point T1, ΔT may be a time difference between the time point T2 and the time point T1, T is a time difference between each time point and the time point T1, and A is a Y-axis intercept of the time point T1. In some embodiments, absolute values of pressure variation amounts obtained at all time points during the period L1 are less than 1 dB.

During the period L2, ΔP may be a pressure difference between the time point T3 and the time point T2, ΔT may be a time difference between the time point T3 and the time point T2, T is a time difference between each time point and the time point T2, and A is a Y-axis intercept of the time point T2. In some embodiments, the time difference between the time point T3 and the time point T2 is set to 0.1 seconds, and the pressure difference between the time point T3 and the time point T2 is greater than 0.03 Pa.

During the period L3, ΔP may be a pressure difference between the time point T4 and the time point T3, ΔT may be a time difference between the time point T4 and the time point T3, T is a time difference between each time point and the time point T3, and A is a Y-axis intercept of the time point T3. In some embodiments, the time difference between the time point T4 and the time point T3 is set to 11 seconds, to ensure that the pressure returns to the steady state.

During the period L4, ΔP may be a pressure difference between the time point T5 and the time point T4, ΔT may be a time difference between the time point T5 and the time point T4, T is a time difference between each time point and the time point T4, and A is a Y-axis intercept of the time point T4. In some embodiments, absolute values of pressure variation amounts obtained at all the time points during the period L4 are less than 1 dB.

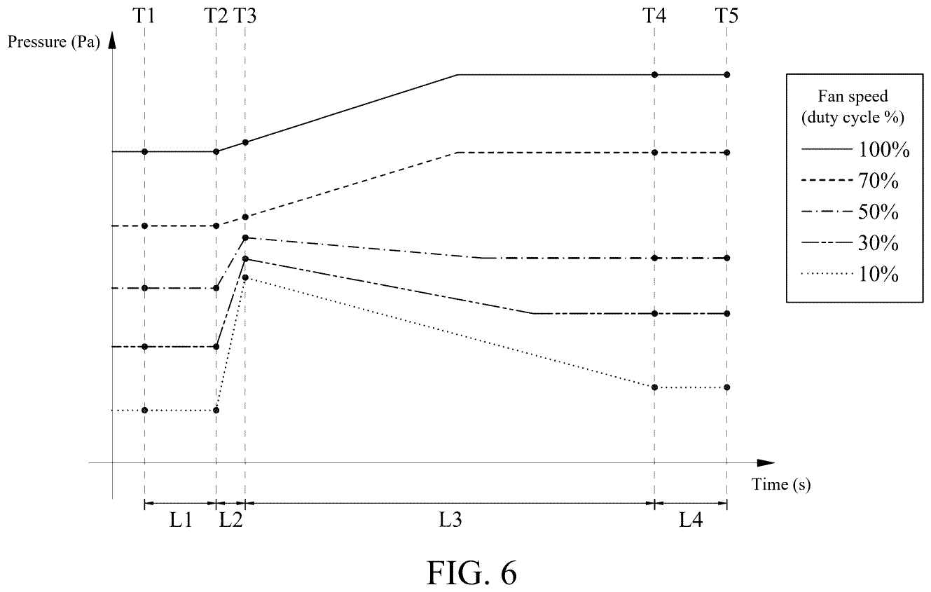

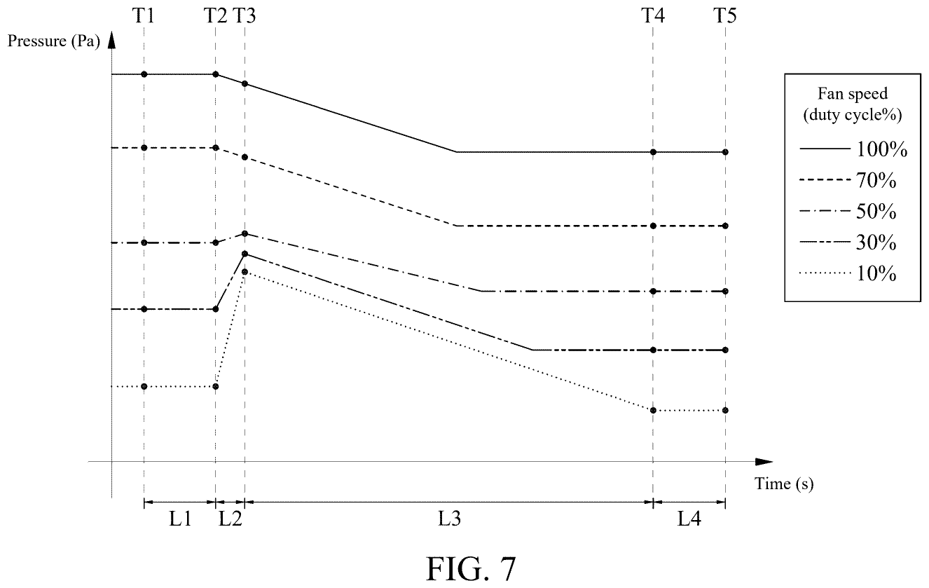

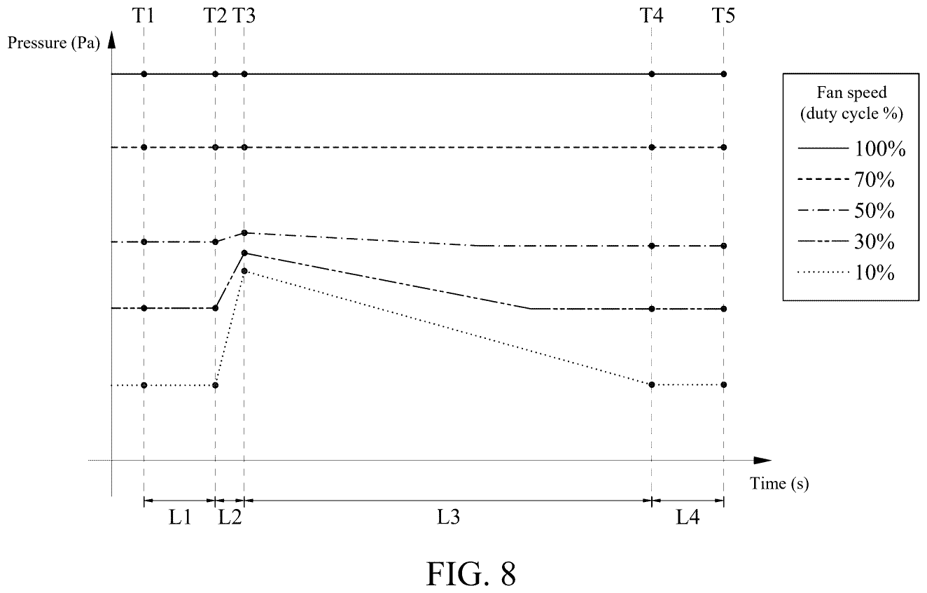

As described above, the speed value of the fan 12 is related to pressure values during the steady state and the transient state, and is also related to the pressure variation value in the steady state. FIG. 6 to FIG. 8 are schematic diagrams of pressure sensing signal variations under different fan speed statuses according to different embodiments. FIG. 6 shows a scene in which the cover 112 is placed over the housing 111 from a detached state. FIG. 7 shows a scene in which the cover 112 is detached from the housing 111 from a covered state. FIG. 8 shows a scene in which the cover 112 maintains to cover the housing 111. Referring to FIG. 6 to FIG. 8 together, a higher speed of the fan 12 indicates a larger pressure variation value in steady states (that is, the period L1 and the period L4). The pressure variation value affects the slope ΔP/ΔT in Formula 1. Therefore, slopes ΔP/ΔT obtained by the fan 12 at different speeds are different, to form a slope range. As shown in FIG. 6, the pressure variation value between the time point T4 and the time point T2 when the speed of the fan 12 is the duty cycle 10% is less than the pressure variation value between the time point T4 and the time point T2 when the speed of the fan 12 is the duty cycle 100%. When the pressure variation state is an increase, a slope range obtained at various speeds are defined as a first slope range. As shown in FIG. 7, the pressure variation value between the time point T4 and the time point T2 when the speed of the fan 12 is the duty cycle 10% is less than the pressure variation value between the time point T4 and the time point T2 when the speed of the fan 12 is the duty cycle 100%. When the pressure variation state is a decrease, a slope range obtained at various speeds are defined as a second slope range. As shown in FIG. 8, no matter how the speed of the fan 12 is, the pressure variation value between the time point T4 and the time point T2 is 0.

The slope range may be defined as a steady-state relative pressure difference measured by the pressure sensor 13 before and after the cover is opened (or before and after the cover is closed) when the fan regulating system 10 is under a test condition. Under the test condition, the speed of the fan 12 is set to values between the range from a minimum value to a maximum value, which corresponds to a range of a lower limit to an upper limit of a specification value of operating power of the fan 12; and the cover-opening distance is set to 0 or infinity. Specifically, referring to FIG. 2 and FIG. 3, the pressure sensor 13 in the embodiments is a MEMS microphone, and has a sensitivity of 7.9433 (mV/Pa). Four fans 12 are provided, and a size of each of the fans 12 is 60 mm*60 mm*38 mm. Speed values of the fans 12 are sequentially set to 10% (3000 RPM), 30% (8200 RPM), 50% (14600 RPM), 70% (20400 RPM), and 100% (26200 RPM). For measurement, the cover 112 is partially opened from one side of the opening 1111, and different cover-opening distances are set. The cover-opening distances between a boundary of the cover 112 and a boundary of the opening 1111 of the housing 111 are sequentially set to 0 mm and infinity (that is, the cover 112 is removed). The housing 111 has a housing length L of 505 mm, a housing width W of 360 mm, and a housing height H of 85 mm.

Table 3 presents a slope range of the pressure sensor 13 under a test condition in which the cover is closed and different fan speeds are provided according to some embodiments. Table 4 presents a slope range of the pressure sensor 13 under a test condition in which the cover is opened and different fan speeds are provided according to some embodiments. Referring to Table 3 and Table 4 (shown in the end of the detail description) together, in the embodiments, when the cover 112 is placed over the opening 1111, a slope range of pressure variation values at different speeds of the fan 12 is from 0.3 to 0.6, and an absolute value of a slope is larger as the speed of the fan 12 is higher. When the cover 112 is detached from the opening 1111, a slope range of pressure variation values at different speeds of the fan 12 is from −0.3 to −0.6, and an absolute value of a slope is larger as the speed of the fan 12 is higher. In the embodiments, the slope range reflects a steady-state pressure variation value that could be caused by the state switching event of the fan 12 at different speeds. As shown in Table 3, a lower limit of a slope value under the test condition is 0.3. Considering that the lower limit of the slope value may be 0 under a condition in which the pressure value has no variation, each slope range value may include a permissible error. According to some embodiments, an error value ranges from −0.3 to +0.3. In some embodiments, when the cover 112 is placed over the opening 1111, a value range of the first slope range is from 0 to 0.6; and when the cover 112 is detached from the opening 1111, a value range of the second slope range is from 0 to −0.6, where the first slope range and the second slope range may be parameter values stored in the memory. In the embodiments, the speed of the fan 12 has a linear or nonlinear positive correlation with the absolute value of the slope.

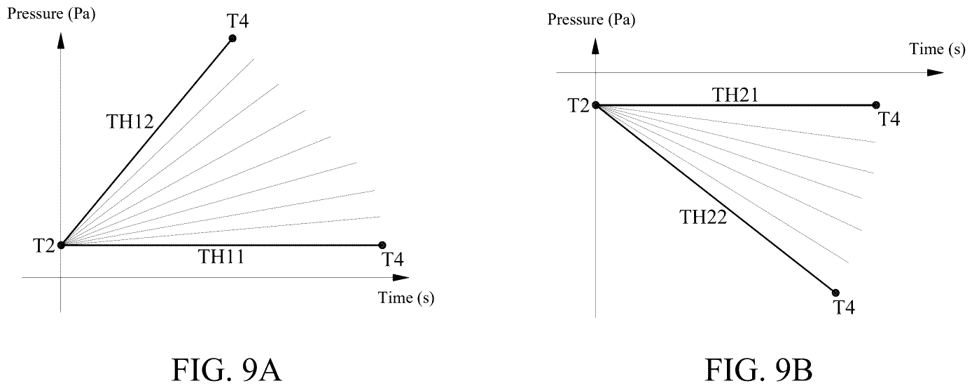

FIG. 9A and FIG. 9B are schematic diagrams of a slope range of pressure sensing signal variations according to different embodiments. Referring to FIG. 9A and FIG. 9B together, FIG. 9A indicates a first slope range upper limit TH12 and a first slope range lower limit TH11 of the first slope range. A plurality of slope values may exist between the first slope range upper limit TH12 and the first slope range lower limit TH11. When the controller 14 determines that the pressure variation state is an increase (in step S04, a determining result is “yes”), the controller 14 further determines whether the pressure variation value is in the first slope range (step S05). Within the first slope range, the plurality of slope values reflect a variation degree of the pressure value when the fan 12 is at different speeds. When the speed of the fan 12 is higher, the slope value is closer to the first slope range upper limit TH12. When the speed of the fan 12 is lower, the slope value is closer to the first slope range lower limit TH11. FIG. 9B indicates a second slope range upper limit TH21 and a second slope range lower limit TH22 of the second slope range. A plurality of slope values may exist between the second slope range upper limit TH21 and the second slope range lower limit TH22. When the controller 14 determines that the pressure variation state is a decrease (in step S04, the determining result is “no”), the controller 14 further determines whether the pressure variation value is in the second slope range (step S06). In the second slope range, the plurality of slope values reflect a variation degree of the pressure value when the fan 12 is at different speeds. When the speed of the fan 12 is higher, the slope value is closer to the second slope range lower limit TH22. When the speed of the fan 12 is lower, the slope value is closer to the second slope range upper limit TH21. In the embodiments, the correlation between the speed of the fan 12 and the slope value is not limited to a linear or nonlinear relationship.

A pressure variation value that may occur inside the chassis 11 under a normal state switching event is reflected within the first slope range and the second slope range. When the pressure variation value is outside the first slope range or the second slope range, it indicates that a pressure variation may not be caused by the state switching event. For example, a temporary pressure variation in the chassis 11 is caused by automatic regulation of the fan 12 or an external factor. In some embodiments, the fan regulating system is a server. The server includes a device controller for controlling the fan 12. The device controller may be a central processing unit (for example, executing a BIOS or unified extensible firmware interface (UEFI) to regulate the speed of the fan 12 to perform heat dissipation management), a baseboard management controller, or another device controller. The speed of the fan 12 may be regulated by one or more device controllers, depending on whether each device controller obtains a control permission during regulation. For example, a selection status of the fan 12 is determined through a serial peripheral interface bus (SPI). In addition, a relationship between a duty cycle of a control signal output by each device controller and the increase or decrease of the pressure inside the housing is indirect. Consequently, it is difficult to distinguish whether the pressure variation is caused by the state switching event or the automatic regulation of the fan 12. In view of this, in step S05, it is ensured that the pressure variation is caused by the cover 112 being placed over the housing 111, and in step S06, it is ensured that the pressure variation is caused by the cover 112 being detached from the housing 111.

In the embodiments, when the controller 14 determines that the pressure variation value is in the first slope range (in step S05, a determining result is “yes”), the controller 14 regulates the speed value according to a first mode (step S08). In the embodiments, the controller 14 includes a function of the device controller (for example, the controller 14 is the central processing unit or the baseboard management controller). The controller 14 may be configured to execute the speed regulating program, to regulate the speed value and control the fan 12 accordingly. The first mode may mean that the controller 14 controls the fan 12 according to a system preset value; or the controller 14 controls the fan 12 according to a preset program (for example, regulating the speed of the fan based on a temperature inside the chassis 11, or directly reducing a current speed value). The system preset value may be a preset speed control parameter of the controller 14, where the speed value of the fan 12 corresponding to the preset speed control parameter is less than a maximum speed value of the fan 12; or may be a speed control parameter set by the device controller. In view of this, when the cover 112 is placed over the housing 111, the fan regulating system 10 reduces or maintains the speed value of the fan 12 according to the first mode, to allow the fan regulating system 10 to perform heat dissipation regulation according to an internal state of the closed chassis 11. When the controller 14 determines that the pressure variation value is not in the first slope range (in step S05, the determining result is “no”), the controller 14 ends the speed regulating program (step S07). In some embodiments, when the speed regulating program is ended (step S07), the controller 14 may return to step S01 and continuously detects a pressure state inside the chassis 11; and the controller 14 may set the speed value to the system preset value, to regulate the fan 12.

In the embodiments, when the controller 14 determines that the pressure variation value is in the second slope range (in step S06, a determining result is “yes”), the controller 14 regulates the speed value according to a second mode (step S09). The second mode is different from the first mode in a speed control parameter or a program. The second mode may mean that the controller 14 controls the fan 12 according to a preset speed control parameter (for example, a maximum speed value); or the controller 14 controls the fan 12 according to a preset program (for example, directly increasing a current speed value). In view of this, when the cover 112 is detached from the housing 111, the fan regulating system 10 increases or maintains the speed value of the fan 12 according to the second mode, to allow the fan regulating system 10 to optimize a heat dissipation capability in response to a state of opening the chassis 11. When the controller 14 determines that the pressure variation value is not in the second slope range (in step S06, the determining result is “no”), the controller 14 ends the speed regulating program (step S07). In some embodiments, when the controller 14 determines that the pressure variation value is in the first slope range, the fan regulating system 10 sets the speed value to a first speed value. When the controller 14 determines that the pressure variation value is in the second slope range, the fan regulating system 10 sets the speed value to a second speed value. The second speed value is greater than the first speed value, so that the fan 12 can improve the heat dissipation capability in response to the state of opening the chassis 11.

In conclusion, in some embodiments, the fan regulating system detects the pressure variation inside the chassis by using the pressure sensor. When an operating staff performs an action such as opening or closing the cover, the pressure sensor detects the pressure variation inside the chassis, to transmit a sensing signal to the controller. In some embodiments, the controller calculates, according to the pressure value, a plurality of determining conditions (for example, but not limited to, the instantaneous pressure value, and the pressure variation value) and regulates the speed of the fan based on the plurality of determining conditions and preset parameters (for example, but not limited to, the pressure threshold, the preset period, and the slope range) to optimize heat dissipation performance. In this way, when it is detected that the cover is opened, the fan regulating system can immediately increase the speed of the fan to meet the requirement of heat dissipation, thereby preventing system from crashing due to a heat dissipation problem. When the cover is closed and the system restores to a normal operating environment, the speed of the fan can also be correspondingly regulated back to an optimal operating state. In some embodiments, the pressure sensor has advantages of a small size and easy mounting, without complex mounting and cabling operations, thereby reducing time and workload required for the mounting or a repairing operation. The pressure sensor does not occupy a large amount of mechanism space or circuit board space, and costs of the pressure sensor are relatively low. In some embodiments, the fan regulating system reduces a length of a mechanism component or a cable, effectively manages efficiency of the fan speed, effectively reduces energy consumption while considering the heat dissipation capability, and reduces carbon emission while improving resource utilization, thereby making contributions to environmental protection and permanent development.

Although the present disclosure is disclosed in the above by using embodiments, the embodiments are not intended to limit the present disclosure. Anyone having ordinary knowledge in the technical field can make some changes and refinements without departing from the spirit and scope of the present disclosure. Therefore, the protection scope of the present disclosure is subject to that defined by the attached claims.

TABLE 1
The output voltage differences of the pressure sensor
under the test condition according to some embodiments

| | 10 mm | 30 mm | 100 mm | 250 mm | Infinity |
|---|---|---|---|---|---|
| 10% | 0.26 | 0.80 | 0.94 | 1.46 | 1.47 |
| 30% | 4.80 | 6.17 | 7.04 | 10.63 | 10.68 |
| 50% | 11.39 | 16.73 | 19.07 | 26.99 | 26.99 |
| 70% | 17.42 | 26.16 | 31.79 | 44.14 | 44.26 |
| 100% | 27.10 | 60.97 | 76.97 | 100.18 | 98.54 |

Note:
column: cover-opening distance; row: speed duty cycle; and value unit: mV

TABLE 2
The pressure differences obtained through conversion
on the output voltage differences in Table 1

| | 10 mm | 30 mm | 100 mm | 250 mm | Infinity |
|---|---|---|---|---|---|
| 10% | 0.03 | 0.10 | 0.12 | 0.18 | 0.18 |
| 30% | 0.60 | 0.78 | 0.89 | 1.34 | 1.34 |
| 50% | 1.43 | 2.11 | 2.40 | 3.40 | 3.40 |
| 70% | 2.19 | 3.29 | 4.00 | 5.56 | 5.57 |
| 100% | 3.41 | 7.68 | 9.69 | 12.61 | 12.41 |

Note:
column: cover-opening distance; row: speed duty cycle; and value unit: Pa

TABLE 3
The slope range of the pressure sensor 13 under the test
condition in which the cover is closed and different
fan speeds are provided according to some embodiments

| Speed duty cycle | 10% | 30% | 50% | 70% | 100% |
|---|---|---|---|---|---|
| Time point T2 | 4.50 | 4.40 | 4.30 | 5.20 | 4.70 |
| Time point T4 | 15.60 | 15.50 | 15.40 | 16.30 | 15.80 |
| Duration | 11.10 | 11.10 | 11.10 | 11.10 | 11.10 |
| Pressure value at | 60.80 | 72.00 | 83.90 | 91.60 | 97.20 |
| the time point T2 | | | | | |
| Pressure value at | 63.70 | 77.00 | 88.30 | 95.80 | 103.40 |
| the time point T4 | | | | | |
| Pressure difference | 2.91 | 5.00 | 4.40 | 4.20 | 6.20 |
| Slope | 0.30 | 0.50 | 0.40 | 0.40 | 0.60 |

Note:
the duration is a sum of the duration L2 and the duration L3, the pressure difference is a value difference between the pressure value at the time point T4 and the pressure value at the time point T2, and the slope is equal to the pressure difference/the duration; time unit: s; and pressure unit: Pa.

TABLE 4
The slope range of the pressure sensor 13 under the test
condition in which the cover is opened and different
fan speeds are provided according to some embodiments

| Speed duty cycle | 10% | 30% | 50% | 70% | 100% |
|---|---|---|---|---|---|
| Time point T2 | 5.30 | 7.80 | 5.50 | 4.50 | 7.30 |
| Time point T4 | 16.40 | 18.90 | 16.60 | 15.60 | 18.40 |
| Duration | 11.10 | 11.10 | 11.10 | 11.10 | 11.10 |
| Pressure value at | 63.90 | 77.70 | 88.60 | 96.60 | 103.60 |
| the time point T2 | | | | | |
| Pressure value at | 60.80 | 71.90 | 84.20 | 91.80 | 97.40 |
| the time point T4 | | | | | |
| Pressure difference | 3.10 | 5.80 | 4.40 | 4.80 | 6.10 |
| Slope | −0.30 | −0.50 | −0.40 | −0.40 | −0.60 |

Note:
the duration is a sum of the duration L2 and the duration L3, the pressure difference is a value difference between the pressure value at the time point T4 and the pressure value at the time point T2, and the slope is equal to the pressure difference/the duration; time unit: s; and pressure unit: Pa.

What is claimed is:

1. A fan regulating system, comprising:
a chassis, including a housing and a cover, the housing having an opening, and the cover being configured to cover the opening;
a fan, arranged inside the housing, the fan having a vent;
a pressure sensor, arranged inside the housing and adjacent to the vent, the pressure sensor being configured to measure a pressure value in the chassis; and
a controller, coupled to the pressure sensor and the fan, the controller being configured to calculate a plurality of determining conditions according to the pressure value and to regulate a speed value of the fan according to the plurality of determining conditions.

2. The fan regulating system according to claim 1, further comprising a main board, wherein the controller is arranged on the main board, the vent of the fan faces the main board, and the pressure sensor is coupled to the main board and arranged between the vent and the main board.

3. The fan regulating system according to claim 1, further comprising a main board, wherein the controller and the pressure sensor are arranged on the main board, and the vent of the fan faces the main board.

4. The fan regulating system according to claim 1, wherein the controller is configured to execute a speed regulating program, and the speed regulating program calculates an instantaneous pressure value according to the pressure value, and determines whether a state switching event has occurred.

5. The fan regulating system according to claim 4, wherein in response to the instantaneous pressure value being greater than a pressure threshold, the speed regulating program further determines whether the cover is placed over the opening or is detached from the opening according to a pressure variation value of the pressure value before and after a preset period.

6. The fan regulating system according to claim 5, wherein
in response to the pressure variation value being greater than an upper limit of a pressure difference range, the speed regulating program further determines whether the pressure variation value is in a first slope range; and
in response to the pressure variation value being less than a lower limit of the pressure difference range, the speed regulating program further determines whether the pressure variation value is in a second slope range.

7. The fan regulating system according to claim 6, wherein in response to the pressure variation value being in the first slope range, the speed regulating program further controls the speed value according to a first mode.

8. The fan regulating system according to claim 7, wherein the speed regulating program reduces the speed value.

9. The fan regulating system according to claim 7, wherein in response to the pressure variation value being in the second slope range, the speed regulating program further controls the speed value according to a second mode, wherein the first mode is different from the second mode.

10. The fan regulating system according to claim 9, wherein the speed regulating program increases the speed value to a maximum value.

11. The fan regulating system according to claim 6, wherein
in response to the pressure variation value being in the first slope range, the speed regulating program further sets the speed value to a first speed value; and
in response to the pressure variation value being in the second slope range, the speed regulating program further sets the speed value to a second speed value, wherein the second speed value is greater than the first speed value.

12. The fan regulating system according to claim 6, wherein in response to the pressure variation value being outside the first slope range or being outside the second slope range, the controller ends the speed regulating program.

13. The fan regulating system according to claim 6, wherein in response to the pressure variation value being in the pressure difference range, the controller ends the speed regulating program.

14. The fan regulating system according to claim 4, wherein in response to the instantaneous pressure value being less than a pressure threshold, the controller ends the speed regulating program.

15. A fan speed regulating method, for regulating a fan, the fan speed regulating method comprising:
reading a pressure value;
calculating an instantaneous pressure value according to the pressure value;
in response to the instantaneous pressure value being greater than a pressure threshold, obtaining a pressure variation value before and after a preset period;
in response to the pressure variation value being less than a lower limit of a pressure difference range, determining whether the pressure variation value is in a second slope range; and
in response to the pressure variation value being in the second slope range, increasing a speed value of the fan.

16. The fan speed regulating method according to claim 15, further comprising:
in response to the pressure variation value being greater than an upper limit of the pressure difference range, determining whether the pressure variation value is in a first slope range; and
in response to the pressure variation value being in the first slope range, controlling the speed value according to a first mode.

17. The fan speed regulating method according to claim 16, further comprising:
in response to the pressure variation value being in the first slope range, setting the speed value to a first speed value; and
in response to the pressure variation value being in the second slope range, setting the speed value to a second speed value, wherein the second speed value is greater than the first speed value.

18. The fan speed regulating method according to claim 16, further comprising: in response to the pressure variation value being outside the first slope range or being outside the second slope range, ending the fan speed regulating method.

19. The fan speed regulating method according to claim 16, further comprising: in response to the pressure variation value being in the pressure difference range, ending the fan speed regulating method.

20. The fan speed regulating method according to claim 16, further comprising: in response to the instantaneous pressure value being less than the pressure threshold, ending the fan speed regulating method.
